(19) United States
(12) Patent Application Publication
(10) Pub. No.: US 2020/0116797 A1
(43) Pub. Date: Apr. 16, 2020

(54) DERIVATION DEVICE, DERIVATION METHOD, AND STORAGE MEDIUM

(71) Applicant: HONDA MOTOR CO., LTD., Tokyo (JP)

(72) Inventors: Taisuke Tsurutani, Wako-shi (JP); Taisuke Kurachi, Wako-shi (JP)

(21) Appl. No.: 16/574,137

(22) Filed: Sep. 18, 2019

(30) Foreign Application Priority Data
Oct. 10, 2018 (JP) 2018-192070

(51) Int. Cl. G01R 31/392; H01M 10/48; B60L 53/62

(52) U.S. Cl. CPC G01R 31/392; H01M 10/48; B60L 58/16; H01M 2220/20; B60L 53/62

(57) ABSTRACT

A derivation device includes an acquirer configured to acquire a capacity retention rate and an output retention rate of a secondary battery that is configured to supply power for traveling of a vehicle, and a deriver configured to derive information on a capacity of the secondary battery using the capacity retention rate and the output retention rate.

### CROSS-REFERENCE TO RELATED APPLICATION

Priority is claimed on Japanese Patent Application No. 2018-192070, filed Oct. 10, 2018, the content of which is incorporated herein by reference.

### BACKGROUND

### Field of the Invention

The present invention relates to a derivation device, a derivation method, and a storage medium.

### Description of Related Art

There are electric vehicles including a motor for traveling, or a hybrid vehicle including a driving motor and an engine. The motor mounted in a vehicle is driven with power supplied from a secondary battery such as a battery. Secondary batteries have problems such as a decrease in the amount of charge due to deterioration. Therefore, there is a technology for determining a deterioration state of a secondary battery (for example, Japanese Unexamined Patent Application, First Publication No. 2018-98947).

### SUMMARY

In the technology disclosed in Patent Document 1, the deterioration state of the secondary battery is determined on the basis of a current full charge capacity or an initial full charge capacity of the secondary battery. However, it is difficult to say that various types of information are sufficiently utilized when information on a capacity of the secondary battery such as a health state of the secondary battery is derived.

The present invention has been made in consideration of such circumstances, and an object of the present invention is to provide a derivation device, a derivation method, and a storage medium capable of deriving information on a capacity of a secondary battery by sufficiently utilizing various types of information.

The derivation device, the derivation method, and the storage medium according to the present invention have adopted the following configurations.

(1) An aspect of the present invention is a derivation device including: an acquirer configured to acquire a capacity retention rate and an output retention rate of a secondary battery that is configured to supply power for traveling of a vehicle; and a deriver configured to derive information on a capacity of the secondary battery using the capacity retention rate and the output retention rate.

(2) In the aspect of (1), the deriver is configured to derive a capacity deterioration state of the secondary battery on the basis of the capacity retention rate and the output retention rate.

(3) In the aspect of (2), the deriver is configured to adjust a use ratio between the capacity retention rate and the output retention rate at the time of derivation of the capacity deterioration state of the secondary battery, according to a magnitude relationship between the capacity retention rate and the output retention rate.

(4) In the aspect of (3), the deriver is configured to derive an average value of the capacity retention rate and the output retention rate as the capacity deterioration state when the output retention rate is lower than the capacity retention rate, and derive a capacity deterioration rate of the secondary battery as the capacity deterioration state when the output retention rate is not lower than the capacity retention rate.

(5) In the aspect of (2), the deriver is configured to adjust a use ratio between the capacity retention rate and the output retention rate at the time of derivation of the capacity deterioration state of the secondary battery, according to a magnitude relationship between a degree of progress of capacity deterioration of the secondary battery and a degree of progress of output deterioration of the secondary battery.

(6) In the aspect of (1), the deriver is configured to derive corrected battery capacity information on a corrected battery capacity obtained by subtracting a correction amount from a battery capacity of the secondary battery according to a charging rate correction value determined on the basis of the output retention rate of the secondary battery.

(7) In the aspect of (6), the deriver is configured to decrease the charging rate correction value when the output retention rate of the secondary battery is higher.

(8) An aspect of the present invention is a derivation method including: acquiring, by a computer, a capacity retention rate and an output retention rate of a secondary battery that is configured to supply power for traveling of a vehicle; and deriving, by the computer, information on a capacity of the secondary battery using the capacity retention rate and the output retention rate.

(9) An aspect of the present invention is a storage medium storing a program causing a computer to: acquire a capacity retention rate and an output retention rate of a secondary battery that is configured to supply power for traveling of a vehicle; and derive information on a capacity of the secondary battery using the capacity retention rate and the output retention rate.

According to the aspects of (1) to (9), it is possible to derive information on the capacity of the secondary battery by sufficiently utilizing various types of information.

### BRIEF DESCRIPTION OF THE DRAWINGS

FIG. 1 is a diagram showing a configuration example of a derivation system according to a first embodiment.

FIG. 2 is a diagram showing an example of a configuration of a vehicle.

FIG. 3 is a diagram showing a configuration of a vehicle cabin of a vehicle.

FIG. 4 is a flowchart showing an example of a flow of a process that is executed by each unit of a center server.

FIG. 5 is a flowchart showing an example of a flow of a process that is executed by each unit of a center server.

FIG. 6 is a graph showing an example of temporal change in a capacity retention rate, an output retention rate, and an SOH of a battery.

FIG. 7 is a diagram showing a relationship between an output retention rate and a correction SOC stored in a storage.

FIG. 8 is a diagram showing an SOC when the battery is new and when the battery has deteriorated.

FIG. 9 is a diagram showing an example of a configuration of a vehicle according to a second embodiment.

FIG. 10 is a flowchart showing a modification example of a flow of a process that is executed by each unit of the center server.

### DESCRIPTION OF EMBODIMENTS

Hereinafter, embodiments of a derivation device, a derivation method, and a storage medium of the present invention will be described with reference to the drawings. Although the vehicle 10 is an electric vehicle in the following description, the vehicle 10 may be a vehicle in which a secondary battery that supplies power for traveling has been mounted or may be a hybrid vehicle or a fuel cell vehicle.

### First Embodiment

### [Overall Structure]

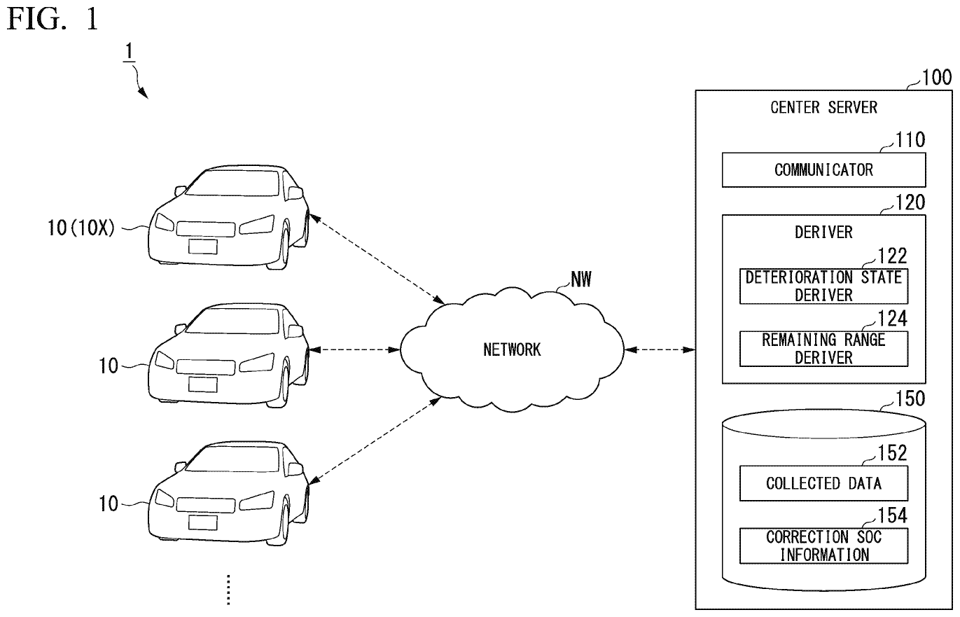

FIG. 1 is a diagram showing a configuration example of the derivation system 1 according to a first embodiment. The derivation system 1 is a system that is configured to derive information on a capacity of a battery (hereinafter, this is assumed to be synonymous with a secondary battery) mounted in a vehicle 10. As shown in FIG. 1, the derivation system 1 includes a plurality of vehicles 10 and a center server (an example of a derivation device) 100. In the following description, it is assumed that, among the plurality of vehicles 10, the vehicle 10 that transmits battery use status information and performs a display based on information transmitted by the center server 100 is a target vehicle 10X.

The center server 100 derives information on a capacity of batteries 40 mounted in the plurality of vehicles 10 on the basis of information transmitted by the plurality of vehicles 10. The vehicles 10 and the center server 100 communicate via a network NW. The network NW includes, for example, the Internet, a wide area network (WAN), a local area network (LAN), a provider device, or a wireless base station.

### [Vehicle 10]

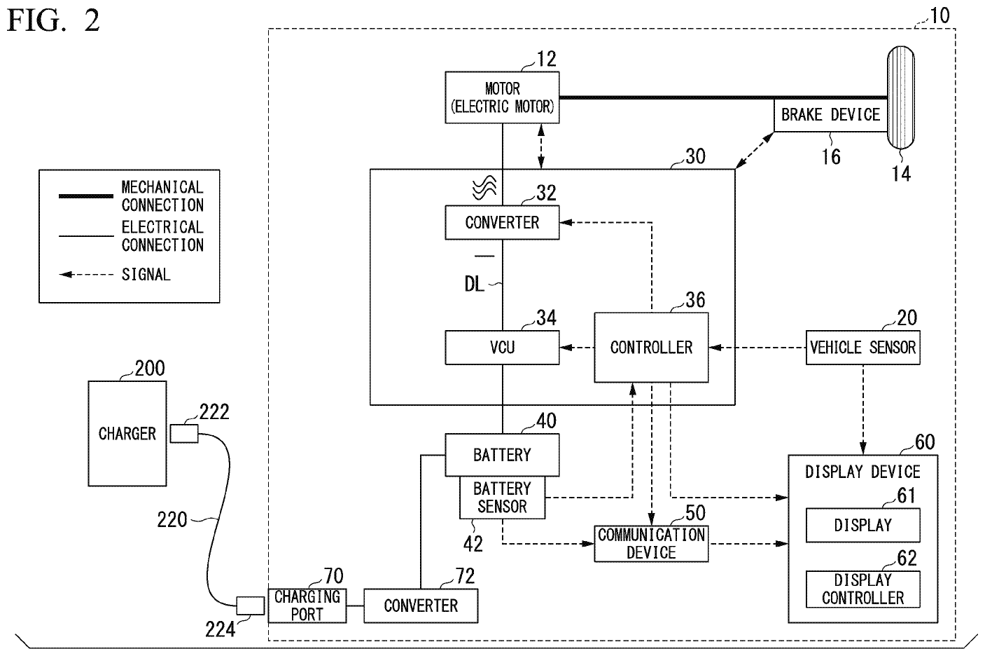

FIG. 2 is a diagram showing an example of a configuration of the vehicle 10. As shown in FIG. 2, the vehicle 10 includes, for example, a motor 12, a drive wheel 14, a brake device 16, a vehicle sensor 20, a power control unit (PCU) 30, the battery 40, a battery sensor 42 such as a voltage sensor, a current sensor, or a temperature sensor, a communication device 50, a display device 60, a charging port 70, and a converter 72.

The motor 12 is, for example, a three-phase alternating current motor. A rotor of the motor 12 is coupled to the drive wheel 14. The motor 12 outputs motive power to the drive wheel 14 using supplied power. The motor 12 generates electricity using kinetic energy of the vehicle at the time of deceleration of the vehicle.

The brake device 16 includes, for example, a brake caliper, a cylinder that transfers hydraulic pressure to the brake caliper, and an electric motor that causes hydraulic pressure to be generated in the cylinder. The brake device 16 may include a mechanism that transfers the hydraulic pressure generated by an operation of a brake pedal to the cylinder via a master cylinder as a backup. The brake device 16 is not limited to the configuration described above and may be an electronically controlled hydraulic brake device that transfers the hydraulic pressure of the master cylinder to the cylinder.

The vehicle sensor 20 includes an accelerator opening degree sensor, a vehicle speed sensor, and a brake depression amount sensor. The accelerator opening degree sensor is attached to an accelerator pedal, which is an example of an operator that receives an acceleration instruction from a driver, detects an amount of operation of the accelerator pedal, and outputs the amount of operation to the controller 36 as an accelerator opening degree. The vehicle speed sensor includes, for example, wheel speed sensors attached to respective wheels, and a speed calculator, integrates wheel speeds detected by the wheel speed sensors to derive a speed of the vehicle (a vehicle speed), and outputs the speed to the controller 36 and the display device 60. The brake depression amount sensor is attached to a brake pedal, detects the amount of operation of the brake pedal, and outputs the amount of operation as a brake pedal amount to the controller 36.

The PCU 30 includes, for example, a converter 32, a voltage control unit (VCU) 34, and a controller 36. A configuration in which these components are formed as the PCU 34 which is a single entity is merely an example, and these components may be disposed in a distributed manner.

The converter 32 is, for example, AC-DC converter. A direct current side terminal of the converter 32 is connected to a DC link DL. The battery 40 is connected to the DC link DL via the VCU 34. The converter 32 converts an alternating current generated by the motor 12 into a direct current and outputs the direct current to the direct current link DL.

The VCU 34 is, for example, a DC-DC converter. The VCU 34 boosts a power supplied from the battery 40 and outputs the boosted power to the DC link DL.

The controller 36 includes, for example, a motor controller, a brake controller, and a battery and VCU controller. The motor controller, the brake controller, and the battery and VCU controller may be replaced with separate control devices, for example, control devices such as a motor ECU, a brake ECU, or a battery ECU.

The controller 36 includes a mode controller for performing traveling control according to a traveling mode selected from among a plurality of traveling modes. For example, a saving mode, a high output mode, or a standard mode is set as the traveling mode. The saving mode is, for example, a mode in which power consumption is suppressed even when traveling performance is lowered, and the high output mode is, for example, a mode in which the traveling performance is enhanced even when the power consumption is increased. The standard mode is a mode between the saving mode and the high output mode.

The motor controller controls the motor 12 on the basis of an output of the vehicle sensor 20. The brake controller controls the brake device 16 on the basis of the output of the vehicle sensor 20. The battery and VCU controller calculate a state of charge (SOC; hereinafter also referred to as a “battery charging rate”) of the battery 40 on the basis of an output of the battery sensor 42 mounted in the battery 40, and output the SOC to the VCU 34 and the display device 60. The VCU 34 increases a voltage of the DC link DL according to an instruction from the battery and VCU controller. The motor controller calculates a power consumption of the vehicle 10 on the basis of the output of the vehicle sensor 20 and a transition of the SOC of the battery 40. The motor controller calculates the power consumption of the vehicle 10 for each traveling mode. The motor controller outputs the calculated power consumption to the communication device 50 as power consumption information.

The battery 40 is, for example, a secondary battery such as a lithium ion battery. The battery 40 stores power introduced from the charger 200 outside the vehicle 10, and performs discharging for traveling of the vehicle 10. The battery sensor 42 includes, for example, a current sensor, a voltage sensor, and a temperature sensor. The battery sensor 42 detects, for example, a current value, a voltage value, and a temperature of the battery 40. The battery sensor 42 outputs the detected current value, voltage value, temperature, and the like to the controller 36 and the communication device 50.

The communication device 50 includes a wireless module for connection of a cellular network or a Wi-Fi network. The communication device 50 acquires battery use status information such as the current value, the voltage value, and the temperature output from the battery sensor 42, and transmits the battery use status information to the center server 100 via the network NW shown in FIG. 1. The communication device 50 transmits the power consumption information output by the motor controller of the controller 36 to the center server 100. The communication device 50 adds type information of a battery and vehicle type information of a host vehicle to the battery use status information and the power consumption information to be transmitted. The communication device 50 receives information transmitted by the center server 100 via the network NW. The communication device 50 outputs the received information to the display device 60.

The display device 60 includes, for example, a display 62 and a display controller 64. The display 62 displays information according to control of the display controller 64. The display controller 64 causes the display 62 to display an image based on the information transmitted by the center server 100 according to information output by the controller 36 and the communication device 50. The display controller 64 causes the display 62 to display the vehicle speed output by the vehicle sensor 20, and the like.

The charging port 70 is provided toward the outside of a vehicle body of the vehicle 10. The charging port 70 is connected to charger 200 through a charging cable 220. The charging cable 220 includes a first plug 222 and a second plug 224. The first plug 222 is connected to the charger 200, and the second plug 224 is connected to the charging port 70. Electricity supplied from the charger 200 is supplied to the charging port 70 via the charging cable 220.

The charging cable 220 includes a signal cable attached to a power cable. The signal cable mediates communication between the vehicle 10 and the charger 200. Therefore, a power connector and a signal connector are provided in each of the first plug 222 and the second plug 224.

The converter 72 is provided between the charging port 70 and the battery 40. The converter 72 converts a current introduced from the charger 200 via the charging port 70, for example, an alternating current into a direct current. The converter 72 outputs the converted direct current to the battery 40.

FIG. 2 is a diagram showing a configuration of a vehicle cabin of the vehicle 10. As shown in FIG. 2, for example, a steering wheel 91 that controls steering of the vehicle M, a front windshield 92 that separates the outside of the vehicle from the vehicle cabin, and an instrument panel 93 are provided in the vehicle 10. The front windshield 92 is a member having light transparency.

The display 62 of the display device 60 is provided near the front of a driver's seat 94 in the instrument panel 93 in the vehicle cabin. The display 62 can be visually recognized by the driver from a gap of the steering wheel 91 or through the steering wheel 91. A second display device 95 is provided at a center of the instrument panel 93. The second display device 95 displays, for example, an image corresponding to a navigation process performed by a navigation device (not shown) mounted in the vehicle 10 or displays an image of another party in a videophone, or the like. The second display device 95 may display a television program, perform playback of a DVD, or display content such as a downloaded movie.

### [Center Server 100]

Referring back to FIG. 1, the center server 100 includes, for example, a communicator (acquirer) 110, a deriver 120, and a storage 150. The deriver 120 is realized, for example, by a hardware processor such as a central processing unit (CPU) executing a program (software). Some or all of these components may be realized by hardware (including circuitry) such as a large scale integration (LSI), an application specific integrated circuit (ASIC), a field-programmable gate array (FPGA), or a graphics processing unit (GPU) or may be realized by software and hardware in cooperation. The program may be stored in a storage (an example of a non-transitory storage medium) such as a hard disk drive (HDD) or a flash memory in advance or may be stored in a removable storage medium (a non-transitory storage medium) such as a DVD or a CD-ROM and the storage medium may be mounted in a drive device so that the program may be installed. The storage 150 is realized by the storage device described above.

The communicator 110 receives and acquires various types of information including the battery use status information such as a current value, a voltage value, a temperature, and the like of the battery transmitted from the plurality of vehicles 10 and the power consumption information. The communicator 110 causes the received information to be stored as collected data 152 in the storage 150 for each piece of identification information of the vehicle 10 (for example, number plate information, communication identification information of the communication device 50, or identification information of a registered user). The type information of the battery or the vehicle type information may be included in the collected data 152.

Each of the plurality of vehicles 10 respectively detects the current value, the voltage value, and the temperature of the battery 40 using the battery sensor 42 on the premise that the process of the center server 100 is performed, and transmits the current value, the voltage value, and the temperature of the battery 40 as battery use status information to the center server 100 using the communication device 50. The plurality of vehicles 10 transmit the power consumption information to the center server 100 together with the battery use status information. The vehicle 10 may perform transmission of the battery use status information and the power consumption information at predetermined time intervals, such as every hour or every day, or may perform the transmission on the basis of an instruction of a user of the vehicle 10. The vehicle 10 may perform transmission of the battery use status information in response to a request from the center server 100. The vehicle 10 may transmit the battery use status information when a predetermined condition is satisfied, for example, when a load of the battery exceeds a certain amount or when the amount of increase in the load of the battery from a previous transmission becomes a certain amount. The vehicle 10 may perform transmission of the battery use status information at any one or more of these timings. The vehicle 10 may perform transmission of the power consumption information at a timing different from that for the battery use status information.

The deriver 120 includes a deterioration state deriver 122 and a remaining range deriver 124. The deterioration state deriver 122 calculates and derives a battery capacity of the battery 40 (a degree of battery deterioration) on the basis of the collected data 152 (the current value, the voltage value, and the temperature of the battery 40) acquired by the communicator 110 and stored in the storage 150. The deterioration state deriver 122 causes the derived battery capacity to be stored as the collected data 152 in the storage 150. The deterioration state deriver 122 calculates and derives a capacity deterioration rate and a capacity retention rate of the battery 40 on the basis of the calculated battery capacity and an initial value of the battery capacity in the collected data 152 stored in the storage 150. The deterioration state deriver 122 causes the derived capacity deterioration rate and the derived capacity retention rate of the battery 40 to be stored as the collected data 152 in the storage 150.

The deterioration state deriver 122 calculates the output of the battery 40 on the basis of the collected data 152 (the current value, the voltage value, and the temperature of the battery 40) acquired by the communicator 110 and stored in the storage 150, and causes the output to be stored as the collected data 152 in the storage 150. The deterioration state deriver 122 calculates and acquires the output retention rate of the battery 40 on the basis of the calculated output of the battery 40 and an initial value of the output of the battery 40 stored in the storage 150. The deterioration state deriver 122 causes the derived output retention rate of the battery 40 to be stored as the collected data 152 in the storage 150.

The deterioration state deriver 122 calculates and derives the capacity deterioration state (a state of health; hereinafter referred to as an “SOH”) of the battery 40 on the basis of the derived battery capacity of the battery 40 and the derived output retention rate of the battery 40. Thus, the deterioration state deriver 122 derives deterioration state information on the SOH which is information on the capacity of the battery 40. The deterioration state deriver 122 outputs the derived deterioration state information on the SOH to the communicator 110. The communicator 110 transmits the deterioration state information output by the deterioration state deriver 122 to the target vehicle 10X.

The remaining range deriver 124 calculates and acquires the capacity deterioration rate of the battery 40 on the basis of the collected data 152 stored in the storage 150. The remaining range deriver 124 may acquire the capacity deterioration rate calculated by the deterioration state deriver 122 instead of calculating the capacity deterioration rate. The remaining range deriver 124 calculates a battery capacity for a traveling range for calculating a remaining travelable distance (hereinafter referred to as a “remaining range”) at the time of traveling in a predetermined traveling mode, such as the standard mode.

The remaining range deriver 124 calculates the output of the battery 40 on the basis of the collected data 152 stored in the storage 150. The remaining range deriver 124 calculates and acquires the output retention rate of the battery 40 on the basis of the calculated output of the battery 40 and the initial value of the output of the battery 40 stored in the storage 150. The remaining range deriver 124 may acquire the output retention rate calculated by the deterioration state deriver 122 instead of calculating the output retention rate.

The storage 150 stores correction SOC information 154 on a correction SOC (a charging rate correction value) that is used when the battery capacity for a traveling range is calculated. The storage 150 stores, as the correction SOC information, a correction SOC in correspondence to the output retention rate. The remaining range deriver 124 reads the correction SOC corresponding to the calculated output retention rate from the storage 150 as the correction SOC that is used when the battery capacity for a traveling range is calculated. The storage 150 stores the correction SOC corresponding to the traveling range.

The remaining range deriver 124 calculates and derives the remaining range in the traveling mode of the vehicle 10 on the basis of the calculated battery capacity for a traveling range. Thus, the remaining range deriver 124 derives remaining range information on the remaining range, which is information on the capacity of the battery 40. The remaining range deriver 124 outputs the derived remaining range information on the remaining range to the communicator 110. The communicator 110 transmits the remaining range information output from the remaining range deriver 124 to the target vehicle 10X.

The target vehicle 10X receives the deterioration state information and the remaining range information transmitted by the communicator 110 of the center server 100 at the communication device 50. The communication device 50 outputs the received deterioration state information and the received remaining range information to the display device 60. The display device 60 causes the SOH based on the deterioration state information and the remaining range based on the remaining range information output by the communication device 50 to be displayed on the display 62 through the display controller 64.

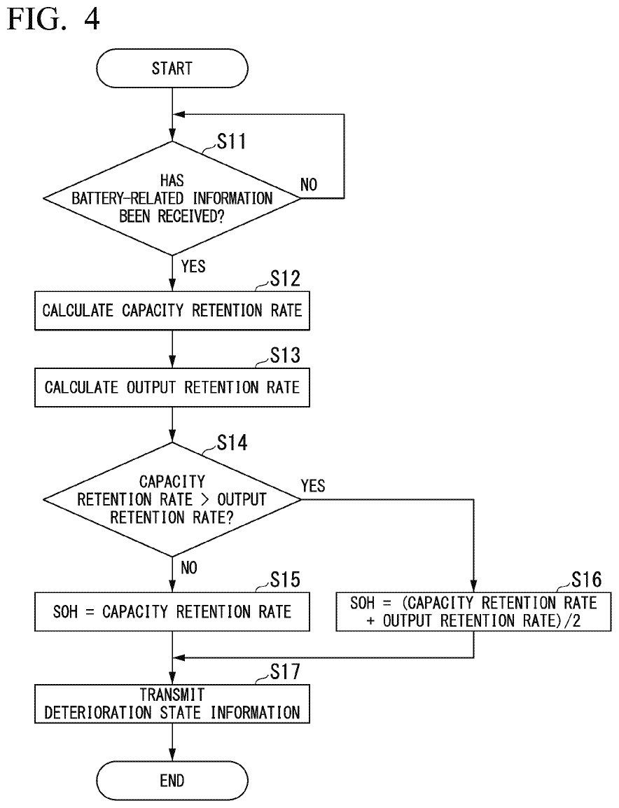

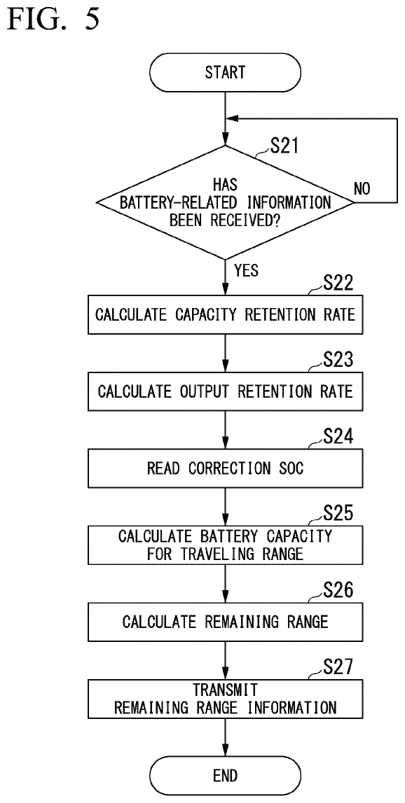

Next, a process in the center server 100 will be described in more detail. FIG. 5 is a flowchart showing an example of a flow of a process that is executed by each unit of the center server 100. Among processes in the center server 100, processes until the deterioration state information is derived and transmitted will be described with reference to FIG. 4, and processes until the remaining range information is derived and transmitted will be described with reference to FIG. 5. The processes shown in FIGS. 4 and 5 may be executed synchronously or asynchronously. An example in which the respective processes are executed asynchronously will be described herein.

### [Process of Deriving Deterioration State Information]

As shown in FIG. 4, the center server 100 determines whether or not the battery use status information transmitted by the target vehicle 10X has been received (step S11). The center server 100 repeats a process of step S11 until the battery use status information is received (step S11: NO).

When it has been determined that the battery use status information has been received (step S11: YES), the center server 100 outputs the battery use status information received by the communicator 110 to the deterioration state deriver 122. The center server 100 causes the battery use status information to be stored in the storage 150. The center server 100 calculates the battery capacity on the basis of the battery use status information (the current value, the voltage value, and the temperature of the battery 40) output by the communicator 110 in the deterioration state deriver 122, and causes the battery capacity to be stored in the storage 150. Subsequently, the center server 100 reads the initial value of the battery capacity of the battery 40 stored in the storage 150, and calculates and derives the capacity retention rate of the battery 40 on the basis of the calculated battery capacity and the read initial value of the battery capacity (step S12).

Subsequently, the center server 100 calculates and derives the output retention rate of the battery 40 in the deterioration state deriver 122 (step S13). The deterioration state deriver 122 calculates the output retention rate of the battery 40 using the following procedure. The deterioration state deriver 122 calculates an internal resistance value of the battery 40 on the basis of the current value and the voltage value of the battery 40 included in the battery use status information in order to calculate the output retention rate. The deterioration state deriver 122 calculates an initial value of the internal resistance value of the battery 40 on the basis of the battery use status information initially transmitted from the battery 40, and causes the initial value to be stored in the storage 150. The deterioration state deriver 122 calculates the internal resistance value of the battery 40 on the basis of the battery use status information transmitted thereafter, and reads the initial value of the internal resistance value stored in the storage 150. The deterioration state deriver 122 calculates and derives the output retention rate on the basis of a ratio between the calculated internal resistance value of the battery 40 and the read initial value of the internal resistance value.

The internal resistance value of the battery 40 can be calculated, for example, using a voltage change amount ΔV and a current change amount ΔI per unit time when the battery 40 is inserted and removed. The deterioration state deriver 122 can calculate a corrected value, for example, by calculating a value obtained using the voltage change amount ΔV and the current change amount ΔI of the battery 40. The deterioration state deriver 122, for example, obtains a statistical slope using a least squares method or performs a (ΔV/ΔI) filter calculation to divide the voltage change amount ΔV by the current change amount ΔI to calculate the value obtained using the voltage change amount ΔV and the current change amount ΔI of the battery 40.

Subsequently, the center server 100 determines whether or not the derived output retention rate is lower than the capacity retention rate using the deterioration state deriver 122 (step S14). As a result, when it has been determined that the output retention rate is not lower than the capacity retention rate (the output retention rate is equal to or higher than the capacity retention rate) (step S14: NO), the deterioration state deriver 122 sets the capacity retention rate of the battery 40 as the SOH (SOH=capacity retention rate) and generates the deterioration state information (step S15). When it has been determined that the output retention rate is lower than the capacity retention rate (step S14: YES), the deterioration state deriver 122 sets an average value of the capacity retention rate and the output retention rate of the battery 40 as the SOH (SOH=(capacity retention rate+output retention rate)/2) and generates the deterioration state information (step S16). Thus, the deterioration state deriver 122 adjusts a use ratio between the capacity retention rate and the output retention rate at the time of derivation of the SOH of the battery 40 according to a magnitude relationship between the capacity retention rate and the output retention rate of the battery 40.

The center server 100 having generated the deterioration state information transmits the deterioration state information generated by the deterioration state deriver 122 to the target vehicle 10X through the communicator 110 (step S17). Thus, the center server 100 ends the process shown in FIG. 4.

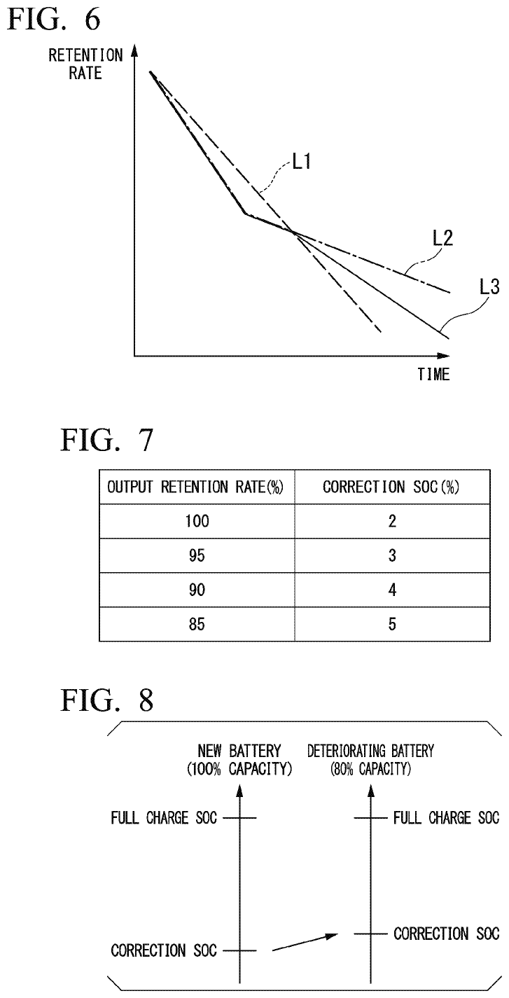

FIG. 6 is a graph showing an example of temporal change in the capacity retention rate of the battery 40, the output retention rate, and the SOH. In FIG. 6, the output retention rate of the battery 40 is indicated by a broken line L1, and the capacity retention rate is indicated by an alternated long and short dash line L2. The SOH of the battery 40 is indicated by a solid line L3. For example, since the remaining range of the target vehicle 10X is determined on the basis of the remaining capacity of the battery 40, it is appropriate for the capacity retention rate to be set as the SOH. However, when the output retention rate extremely deteriorates, there is concern that merchantability deteriorates. Therefore, when the output retention rate deteriorates, the SOH is derived on the basis of both the capacity retention rate and the output retention rate.

As a result, when the output retention rate is not lower than the capacity retention rate as shown in FIG. 6, the deterioration state deriver 122 derives the capacity retention rate as the SOH. When the output retention rate is lower than the capacity retention rate, the deterioration state deriver 122 derives an average value of the capacity retention rate and the output retention rate as the SOH. Thus, the deterioration state deriver 122 of the center server 100 calculates the SOH of the battery 40 using the output retention rate, in addition to the capacity retention rate or the capacity deterioration rate. Therefore, it is possible to perform control regarding the secondary battery by sufficiently utilizing various types of information.

When the capacity retention rate is not lower than the output retention rate, the deterioration state deriver 122 calculates the SOH as the average value of the capacity retention rate and the output retention rate, but the SOH may be calculated in another aspect. For example, the deterioration state deriver 122 may calculate the SOH through a weighted average of the capacity retention rate and the output retention rate, or may adjust a ratio between the capacity retention rate and the output retention rate, for example, set capacity retention rate: output retention rate=3:7 or 7:3 to calculate the SOH.

### [Process of Deriving Remaining Range Information]

Next, a process of deriving the remaining range information will be described with reference to FIG. 5. As shown in FIG. 5, the center server 100 determines whether or not the battery use status information transmitted by the target vehicle 10X has been received (step S21). The center server 100 repeats the process of step S11 until the battery use status information is received (step S21: NO).

When it has been determined that the battery use status information has been received (step S21: YES), the center server 100 calculates the battery capacity on the basis of the battery use status information output by the communicator 110 using the remaining range deriver 124. Then, the center server 100 reads the initial value of the battery capacity of the battery 40 stored in the storage 150 using the remaining range deriver 124, and calculates and derives the capacity retention rate of battery 40 on the basis of the calculated battery capacity and the read initial value of the battery capacity (step S22). Subsequently, the center server 100 calculates and derives the output retention rate of the battery 40 in the remaining range deriver 124 (step S23).

Subsequently, in the center server 100, the remaining range deriver 124 reads the correction SOC from the storage 150 (step S24). FIG. 7 is a diagram showing a relationship between the output retention rate and the correction SOC stored in the storage 150. As shown in FIG. 7, the correction SOC is determined according to the output retention rate. For example, when the output retention rate is 100%, the correction SOC is 2%, and when the output retention rate is 85%, the correction SOC is 5%. The correction SOC decreases when the output retention rate is higher. The relationship shown in FIG. 7 is the correction SOC when the target vehicle 10X travels in the standard mode. The storage 150 may also store correction SOC when the target vehicle 10X travels in the high output mode or the saving mode.

After the correction SOC has been read, the remaining range deriver 124 performs correction using the correction SOC as a correction amount to calculate a battery capacity for a traveling range (a corrected battery capacity) (step S25). A battery capacity for a traveling range Ah is calculated, for example, by subtracting the correction SOC according to Equation (1) below.

Ah=total battery capacity×(full charge SOC−correction SOC)×100 (1)

In Equation (1), the full charge SOC is a full charge SOC of the battery 40 at a point in time when the communicator 110 has received the battery use status information.

The center server 100 calculates the remaining range of the target vehicle 10X on the basis of the battery capacity for a traveling range using the remaining range deriver 124 (step S26). The remaining range deriver 124 calculates the remaining range, for example, by dividing the calculated battery capacity for a traveling range by the power consumption when the target vehicle 10X has traveled in the standard mode (remaining range=battery capacity for traveling range/power consumption at the time of traveling in standard mode). The center server 100 transmits the remaining range information according to the calculated remaining range to the target vehicle 10X (step S27). Thus, the center server 100 ends the process shown in FIG. 5.

FIG. 8 is a diagram showing the SOC when the battery 40 is new or when the battery 40 deteriorates. FIG. 8 shows an example in which a charge capacity of the deteriorating battery 40 is 80% when a charge capacity of the new battery 40 is 100%. As shown in FIG. 8, since the new battery 40 exhibits a high output retention rate, for example, an output retention rate of 100%, the correction SOC is as high as 2%, and as a result, the battery capacity for a traveling range also increases. On the other hand, in the deteriorating battery, since the output maintenance capability decreases, for example, the correction SOC is 5%, the battery capacity for a traveling range eventually decreases. Therefore, a result that a new battery has a longer remaining range than a deteriorating battery can be derived, and a remaining range close to an actual remaining range can be calculated and derived. Therefore, it is possible to perform control regarding the secondary battery by sufficiently utilizing various types of information.

The target vehicle 10X receives the deterioration state information and the remaining range information transmitted by the communicator 110 of the center server 100 in the communication device 50 shown in FIG. 1. The communication device 50 outputs the received deterioration state information and the received remaining range information to the display device 60. The display controller 64 of the display device 60 causes the OSH and the remaining range of the target vehicle 10X to be displayed on the display 62 on the basis of the output deterioration state information and the output remaining range information.

Although the remaining range deriver 124 of the center server 100 derives the remaining range information on the remaining range of the target vehicle 10X, information on the correction SOC or information on the battery capacity for a traveling range (corrected battery capacity information) may be derived for the target vehicle 10X, instead of or in addition to the remaining range information. The remaining range deriver 124 may derive, for example, the remaining range information for different traveling modes, such as the remaining range information when the target vehicle 10X travels in the high output mode or the saving mode, and transmit the remaining range information to the target vehicle 10X. Although the process of deriving the deterioration state information and the process of deriving the remaining range information are executed independently of each other in the first embodiment, these processes may be executed continuously.

According to the first embodiment described above, the deriver 120 of the center server 100 calculates and derives the deterioration state information on the SOH and the remaining range information on the remaining range of the target vehicle 10X as information on the capacity of the battery 40 mounted in the target vehicle 10X. The SOH and the remaining range derived by the deriver 120 are calculated using an output retention rate of the battery 40 and derived, resulting in the SOH and the remaining range with high accuracy. Therefore, it is possible to perform control regarding the secondary battery by sufficiently utilizing various types of information.

In the above embodiment, a capacity retained at a point in time of acquisition of data (the capacity retention rate) and an output retained at the point in time of acquisition of data (the output retention rate) are used as indexes in an initial state for the following reasons. The capacity retention rate decreases with time due to deterioration over time, or the like. Deterioration of the output occurs as an increase in resistance due to physical characteristics of the battery. Accordingly, for example, when an index is expressed as a resistance increase rate, comparison with the capacity retention rate becomes impossible. Therefore, for example, a reference of the output is defined in the form of “an output when a lower limit voltage is 3.0 V in a state in which the SOC is 10% at the battery temperature of 25° C.”, a ratio of the output to an initial output under that condition is set as the output retention rate, and this output retention rate is used as an index.

### Second Embodiment

Next, a second embodiment will be described.

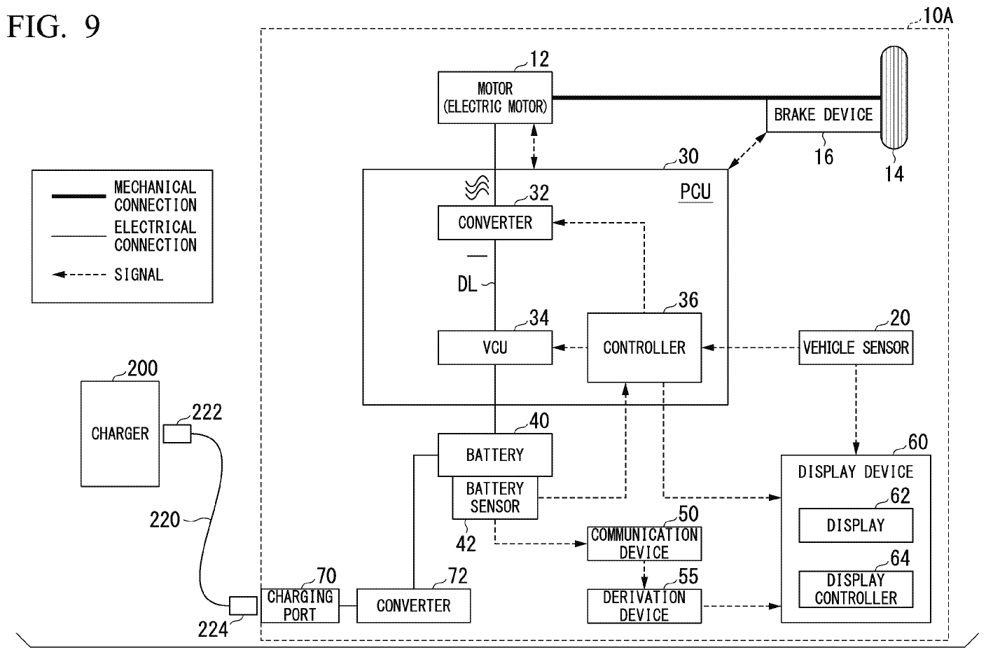

FIG. 9 is a diagram showing an example of a configuration of a vehicle 10A according to the second embodiment.

A configuration in the first embodiment is different from a configuration of the second embodiment in that a component having the same function as the deriver 120 provided in the center server 100 is provided as a derivation device 55 in the vehicle 10A. The communication device is not provided, and a battery sensor 42 outputs a detected current value, a detected voltage value, a detected temperature, and the like to a controller 36 and a derivation device 55. Other points are approximately the same as the configuration in the first embodiment described above. Hereinafter, a process in the second embodiment will be described while focusing on differences with the first embodiment.

The derivation device 55 includes a deterioration state deriver and a remaining range deriver having the same configuration as the deterioration state deriver 122 and the remaining range deriver 124 of the first embodiment, and a storage having the same configuration as the storage 150. The storage of the derivation device 55 stores, for example, correction SOC information in the vehicle 10A. In the second embodiment, the vehicle 10A derives, in the derivation device 55, an SOC of the battery 40 on the basis of, for example, battery use status information of the battery 40 output by a battery sensor 42. The derivation device 55 derives a remaining range on the basis of, for example, the battery use status information of the battery 40 output by the battery sensor 42 and the correction SOC information stored in the storage. The derivation device 55 outputs deterioration state information and remaining range information regarding the derived SOC and the derived remaining range to the display device 60. The display device 60 causes the SOC and the remaining range based on the deterioration state information and the remaining range information output by the derivation device 55 to be displayed on the display 62 through the display controller 64.

According to the second embodiment described above, in the vehicle 10A, the deterioration state information on the SOH and the remaining range information on the remaining range of the target vehicle 10X are calculated and derived as the information on the capacity of the battery 40. The SOH and the remaining range derived in the derivation device 55 are calculated using an output retention rate of the battery 40 and derived, resulting in the SOH and the remaining range with high accuracy. Therefore, it is possible to perform control regarding the secondary battery by sufficiently utilizing various types of information.

In the second embodiment, a travelable distance for a display and remaining life for a display can be derived and displayed in the vehicle 10A without transmission and reception of information to and from a center server 100. Therefore, it is possible to reduce a burden on the center server 100. In the second embodiment, although the vehicle 10A does not include a communication device that performs communication with the center server 100, the vehicle 10A may include the communication device. Initial battery information or the like may be stored in a storage of a server, and the vehicle 10A may cause the center server 100 to transmit the information.

### Modification Example

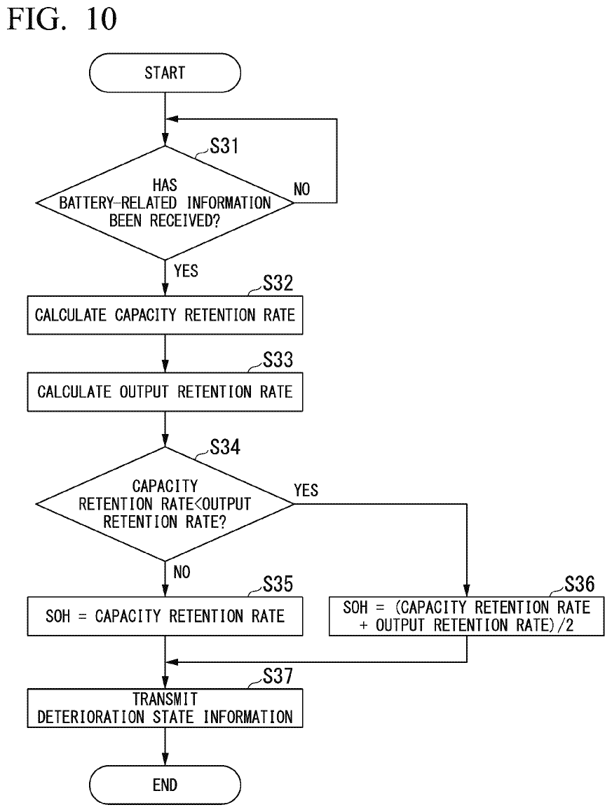

Although the capacity retention rate and the output retention rate of the battery 40 are used when the deterioration state information is derived in the first embodiment, other aspects such as a degree of progress of the capacity retention rate and the output deterioration of the battery 40 may be used. Hereinafter, a procedure of deriving the deterioration state information using the degree of progress of the capacity retention rate and the output deterioration of the battery 40 will be described. FIG. 10 is a flowchart showing a modification example of a flow of process that is executed by each unit of the center server 100.

As shown in FIG. 10, the center server 100 determines whether or not the battery use status information transmitted by the target vehicle 10X has been received (step S31), and the process of step S31 repeats until the battery use status information is received (step S31: NO). When it has been determined that the battery use status information has been received (step S31: YES), the center server 100 outputs the battery use status information received by the communicator 110 to the deterioration state deriver 122, and causes the battery use status information to be stored in the storage 150.

After the center server 100 calculates the battery capacity on the basis of the battery use status information output by the communicator 110 using the deterioration state deriver 122, the center server 100 reads the initial value of the battery capacity of the battery 40 stored in the storage 150, and calculates and derives the capacity retention rate of the battery 40 on the basis of the calculated battery capacity and the read initial value of the battery capacity (step S32). Subsequently, the center server 100 calculates and derives the output retention rate of the battery 40 using the deterioration state deriver 122 (step S33). This process is the same as the process of steps S11 to S13 shown in FIG. 4.

Subsequently, the center server 100 obtains the degree of progress of the capacity deterioration and the degree of progress of the output deterioration using the deterioration state deriver 122, and determines whether the degree of progress of the capacity deterioration is lower than the degree of progress of the output deterioration (step S34). The deterioration state deriver 122 calculates the degree of progress of the capacity deterioration on the basis of a history of the capacity retention rate of the battery 40 among the collected data stored in the storage 150. The deterioration state deriver 122 calculates the degree of progress of the output deterioration on the basis of a history of the output retention rate of the battery 40 among the collected data stored in the storage 150.

For example, it is assumed that a current capacity retention rate is 90% and the capacity retention rate after 15 years is 70%. It is assumed that a current output retention rate is 85% and the output retention rate after 15 years is 80%. The degree of progression of the capacity deterioration in this case is (100−90)/(100−70)=0.333. The degree of progress of the output deterioration is (100−85)/(100−80)=0.75.

When the deterioration state deriver 122 has determined that the degree of progress of the capacity deterioration is not lower than the degree of progress of the output deterioration (step S34: NO), the deterioration state deriver 122 sets the capacity retention rate of the battery 40 as the SOH (SOH=capacity retention rate) and generates the deterioration state information (step S35). When the deterioration state deriver 122 has determined that the degree of progress of the capacity deterioration is less than the progress of output degradation (step S34: YES), the deterioration state deriver 122 sets an average value of the capacity retention rate and the output retention rate of the battery 40 as the SOH (SOH=(capacity retention rate+output retention rate)/2) and generates the deterioration state information (step S36). Thus, the deterioration state deriver 122 adjusts a use ratio between the capacity retention rate and the output retention rate at the time of derivation of the SOH of the battery 40 according to a magnitude relation between the degree of progress of the capacity deterioration and the degree of progress of the output deterioration of the battery 40.

The center server 100 having generated the deterioration state information transmits the deterioration state information generated by the deterioration state deriver 122 to the target vehicle 10X through the communicator 110 (step S37). Thus, the center server 100 ends the process shown in FIG. 10. Thus, the deterioration state information can also be derived by using the degree of progress of the capacity deterioration and the degree of progress of the output deterioration of the battery 40.

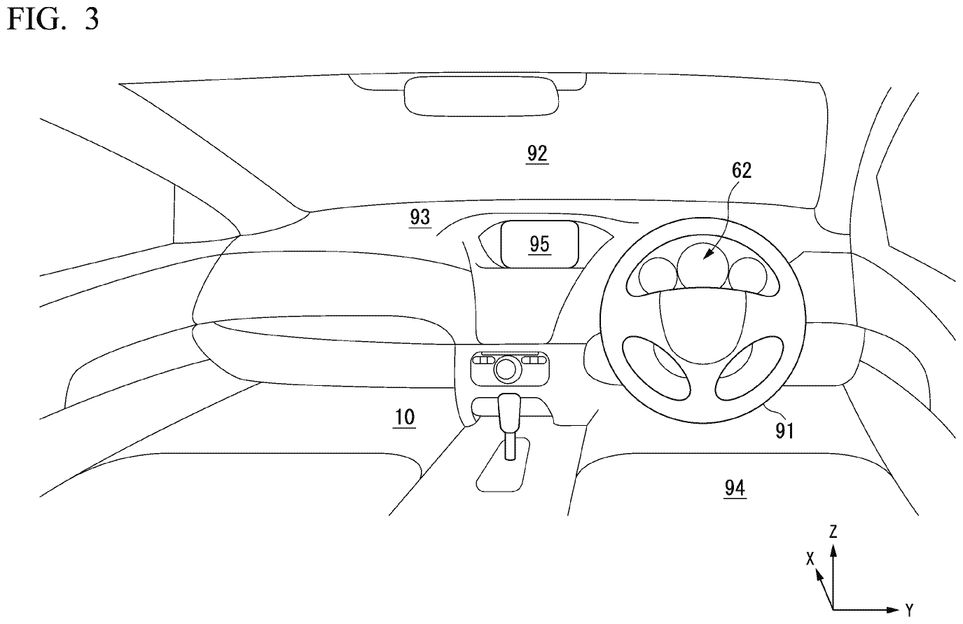

Although in each of the above embodiments, the display device 60 causes the SOH and the remaining range based on the deterioration state information and the remaining range information received by the communication device 50 to be displayed on the display 62 of the target vehicle 10X, the display device 60 may cause the SOH and the remaining range to be displayed on another target. For example, the display controller of the second display device 95 shown in FIG. 3 may cause the SOH and the remaining range to be displayed on the display of the second display device 95, instead of or in addition to the display controller 64 of the display device 60 in the target vehicle 10X causing the SOH and the remaining range to be displayed on the display 62. Alternatively, one of the SOH and the remaining range may be displayed on the display 62 of the display device 60, and the other may be displayed on the second display device 95. Alternatively, the SOH and the remaining range may be displayed on an information terminal or the like possessed by a user of the target vehicle 10X or the like.

A lifetime average temperature of the vehicle 10 may be used when the use ratio between the capacity retention rate and the output retention rate at the time of derivation of the SOH of the battery 40 is adjusted. In the battery 40, a likelihood of adverse effects increases since the output of the battery 40 decreases when the temperature of the vehicle 10 is lower. In consideration of this point, the output retention rate may increase when the lifetime average temperature of the vehicle 10 is lower.

Some of the processes that are performed by the center server 100 may be performed on the vehicle 10 side, or some of the processes that are performed by the vehicle 10 may be performed on the center server 100 side. In this case, the information to be transmitted and received between the vehicle 10 and the center server 100 may be appropriately determined according to generated information.

Although a mode for carrying out the present invention has been described above using the embodiments, the present invention is not limited to the embodiments at all, and various modifications and substitutions may be made without departing from the spirit of the present invention.

What is claimed is:

1. A derivation device comprising:
an acquirer configured to acquire a capacity retention rate and an output retention rate of a secondary battery that is configured to supply power for traveling of a vehicle; and
a deriver configured to derive information on a capacity of the secondary battery using the capacity retention rate and the output retention rate.

2. The derivation device according to claim 1, wherein the deriver is configured to derive a capacity deterioration state of the secondary battery on the basis of the capacity retention rate and the output retention rate.

3. The derivation device according to claim 2, wherein the deriver is configured to adjust a use ratio between the capacity retention rate and the output retention rate at the time of derivation of the capacity deterioration state of the secondary battery, according to a magnitude relationship between the capacity retention rate and the output retention rate.

4. The derivation device according to claim 3,
wherein the deriver is configured to
derive an average value of the capacity retention rate and the output retention rate as the capacity deterioration state when the output retention rate is lower than the capacity retention rate, and
derive a capacity deterioration rate of the secondary battery as the capacity deterioration state when the output retention rate is not lower than the capacity retention rate.

5. The derivation device according to claim 2, wherein the deriver is configured to adjust a use ratio between the capacity retention rate and the output retention rate at the time of derivation of the capacity deterioration state of the secondary battery, according to a magnitude relationship between a degree of progress of capacity deterioration of the secondary battery and a degree of progress of output deterioration of the secondary battery.

6. The derivation device according to claim 1, wherein the deriver is configured to derive corrected battery capacity information on a corrected battery capacity obtained by subtracting a correction amount from a battery capacity of the secondary battery according to a charging rate correction value determined on the basis of the output retention rate of the secondary battery.

7. The derivation device according to claim 6, wherein the deriver is configured to decrease the charging rate correction value when the output retention rate of the secondary battery is higher.

8. A derivation method comprising:
acquiring, by a computer, a capacity retention rate and an output retention rate of a secondary battery that is configured to supply power for traveling of a vehicle; and
deriving, by the computer, information on a capacity of the secondary battery using the capacity retention rate and the output retention rate.

9. A storage medium storing a program causing a computer to:
acquire a capacity retention rate and an output retention rate of a secondary battery that is configured to supply power for traveling of a vehicle; and
derive information on a capacity of the secondary battery using the capacity retention rate and the output retention rate.
